(19) United States
(12) Patent Application Publication
(10) Pub. No.: US 2005/0045983 A1
(43) Pub. Date: Mar. 3, 2005

(54) Semiconductor device and method for manufacturing the same

(76) Inventors: Takafumi Noda, Shiojiri-shi (JP); Masahiro Hayashi, Sakata-shi (JP); Akihiko Ebina, Nagano-ken (JP); Masahiko Tsuyuki, Chino-shi (JP)

Correspondence Address: HARNESS, DICKEY & PIERCE, P.L.C., P.O. BOX 828, BLOOMFIELD HILLS, MI, 48303, US

(21) Appl. No.: 10/899,298

(22) Filed: Jul. 26, 2004

(30) Foreign Application Priority Data
Jul. 28, 2003 (JP) 2003-281036

(51) Int. Cl. H01L 29/00

(52) U.S. Cl. 257/500

(57) ABSTRACT

A semiconductor device is provided that includes a semiconductor layer, first element isolation regions defining a high breakdown voltage transistor forming region in the semiconductor layer, second element isolation regions defining a low voltage driving transistor forming region in the semiconductor layer, high breakdown voltage transistors formed in the high breakdown voltage transistor forming region, low voltage driving transistors formed in the low voltage driving transistor forming region, and offset dielectric layers for alleviating an electric field of the high breakdown voltage transistors, wherein the high breakdown voltage transistors have gate dielectric layers formed by a CVD method.

### RELATED APPLICATIONS

This application claims priority to Japanese Patent Application No. 2003-281036 filed Jul. 28, 2003 which is hereby expressly incorporated by reference herein in its entirety.

### BACKGROUND

The present invention relates to a semiconductor device equipped with MOS transistors (Metal Oxide Semiconductors) having different gate breakdown voltages and drain breakdown voltages on the same semiconductor layer, and a method for manufacturing the same.

Currently, field effect transistors with LOCOS (Local Oxidation Of Silicon) offset structure are regarded as field effect transistors having a higher breakdown voltage design. A field effect transistor having a LOCOS offset structure is a transistor that is provided with a LOCOS layer between a gate dielectric layer and a drain region, and an offset impurity layer below the LOCOS layer.

Also, along with the trend of further weight-reduction and miniaturization of various electronic devices in recent years, there are demands for further reduction in the size of ICs to be mounted on these electronic devices. In particular, for driving ICs in electronic devices having liquid crystal display devices mounted thereon, technologies that reduce chip areas of the ICs through mix-mounting transistors for low voltage operation and high breakdown voltage transistors for high voltage operations on the same substrate (the same chip) are in strong demand. When a high breakdown voltage transistor provided with a LOCOS layer for alleviation of the electric fields described above and a low voltage driving transistor are formed on the same substrate, a semiconductor device of such a structure as described above can be manufactured through, for example, forming a LOCOS layer for element isolation and a LOCOS layer for alleviation of the electric fields in the same step.

However, due to the demands in further miniaturization in recent years, methods for forming element isolation regions are shifting from LOCOS methods to STI (Shallow Trench Isolation) methods, and a method in which LOCOS layers for alleviation of the electric fields of high breakdown voltage transistors are replaced with trench dielectric layers has been proposed. When replacing offset LOCOS layers with trench dielectric layers and forming gate dielectric layers having a great film thickness for high breakdown voltage transistors, thinning occurs at the upper end sections of the trench dielectric layers, and gate dielectric layers having a uniform film thickness may not be formed.

It is an object of the present invention to provide semiconductor devices in which high breakdown voltage transistors and low voltage driving transistors are formed on the same substrate, and semiconductor devices and a method for manufacturing the same which can provide further miniaturization and improved reliability.

### SUMMARY

A semiconductor device in accordance with the present invention comprises:
a semiconductor layer;
a first element isolation region for defining a high breakdown voltage transistor forming region in the semiconductor layer;
a second element isolation region for defining a low voltage driving transistor forming region in the semiconductor layer;
a high breakdown voltage transistor formed in the high breakdown voltage transistor forming region;
a low voltage driving transistor formed in the low voltage driving transistor forming region; and
an offset dielectric layer for alleviating an electric field of the high breakdown voltage transistor, wherein
the high breakdown voltage transistor has a gate dielectric layer formed by a CVD method.

In accordance with the semiconductor device of the present invention, the gate dielectric layer of the high breakdown voltage transistor is a film formed by a CVD method, such that a semiconductor device having the gate dielectric layer with a uniform film thickness can be provided. Often, gate dielectric layers are formed by a thermal oxidation method. For example, when a gate dielectric layer is formed by a thermal oxidation method over an offset dielectric layer composed of a trench dielectric layer, thinning occurs at the upper end sections of the trench dielectric layer, and there are cases where the gate dielectric layer cannot be formed with a uniform film thickness. However, since the semiconductor device in accordance with the present embodiment has a gate dielectric layer formed by a CVD method, such problems can be avoided, and a semiconductor device with an improved reliability can be provided.

The present invention can assume the following embodiments, for example.

In the semiconductor device in accordance with the present invention, the gate dielectric layer of the high breakdown voltage transistor can have a film thickness of about 100-160 nm.

In the semiconductor device in accordance with the present invention, the offset dielectric layer can be a trench dielectric layer.

A method for manufacturing a semiconductor device in accordance with the present invention includes:
a step of forming a first element isolation region for defining a high breakdown voltage transistor forming region in a semiconductor layer;
a step of forming a second element isolation region for defining a low voltage driving transistor forming region in the semiconductor layer;
a step of forming an offset dielectric layer for alleviating an electric field of the high breakdown voltage transistor;
a step of forming a high breakdown voltage transistor in the high breakdown voltage transistor forming region; and
a step of forming a low voltage driving transistor in the low voltage driving transistor forming region,
wherein a gate dielectric layer of the high breakdown voltage transistor is formed by a CVD method.

In accordance with the method for manufacturing a semiconductor device of the present invention, the gate dielectric layer of the high breakdown voltage transistor is formed by a CVD method. For this reason, the gate dielectric layer can be formed with a uniform film thickness. Gate dielectric layers of high breakdown voltage transistors may have a film thickness exceeding 100 nm, and the following problem may occur when gate dielectric layers having such a great film thickness are formed by a thermal oxidation method. When an offset dielectric layer of a high breakdown voltage transistor is formed with a trench dielectric layer, and a gate dielectric layer having a great film thickness is formed by a thermal oxidation method over the trench dielectric layer, thinning occurs at the upper end sections of the trench dielectric layer, and the gate dielectric layer cannot be formed with a uniform film thickness. However, by the method for manufacturing a semiconductor device of the present invention, gate dielectric layers are formed by a CVD method. Accordingly, the problem described above can be avoided, and a semiconductor device having an improved reliability can be manufactured.

The present invention can assume the following embodiments, for example.

In the method for manufacturing a semiconductor device in accordance with the present invention, the offset dielectric layer can be formed by a trench element isolation method.

In the method for manufacturing a semiconductor device in accordance with the present invention, the first and second element isolation regions and the offset dielectric layer can be formed by a common process.

### BRIEF DESCRIPTION OF THE DRAWINGS

FIG. 1 schematically shows a cross-sectional view of a semiconductor device in accordance with an embodiment of the present invention.

FIG. 2 schematically shows a cross-sectional view illustrating a step in the method for manufacturing a semiconductor device in accordance with the embodiment of the present invention.

FIG. 3 schematically shows a cross-sectional view illustrating a step in the method for manufacturing a semiconductor device in accordance with the embodiment of the present invention.

FIG. 4 schematically shows a cross-sectional view illustrating a step in the method for manufacturing a semiconductor device in accordance with the embodiment of the present invention.

FIG. 5 schematically shows a cross-sectional view illustrating a step in the method for manufacturing a semiconductor device in accordance with the embodiment of the present invention.

FIG. 6 schematically shows a cross-sectional view illustrating a step in the method for manufacturing a semiconductor device in accordance with the embodiment of the present invention.

FIG. 7 schematically shows a cross-sectional view illustrating a step in the method for manufacturing a semiconductor device in accordance with the embodiment of the present invention.

FIG. 8 schematically shows a cross-sectional view illustrating a step in the method for manufacturing a semiconductor device in accordance with the embodiment of the present invention.

FIG. 9 schematically shows a cross-sectional view illustrating a step in the method for manufacturing a semiconductor device in accordance with the embodiment of the present invention.

FIG. 10 schematically shows a cross-sectional view illustrating a step in the method for manufacturing a semiconductor device in accordance with the embodiment of the present invention.

FIG. 11 schematically shows a cross-sectional view illustrating a step in the method for manufacturing a semiconductor device in accordance with the embodiment of the present invention.

FIG. 12 schematically shows a cross-sectional view illustrating a step in the method for manufacturing a semiconductor device in accordance with the embodiment of the present invention.

FIG. 13 schematically shows a cross-sectional view illustrating a step in the method for manufacturing a semiconductor device in accordance with the embodiment of the present invention.

FIG. 14 schematically shows a cross-sectional view illustrating a step in the method for manufacturing a semiconductor device in accordance with the embodiment of the present invention.

FIG. 15 schematically shows a cross-sectional view illustrating a step in the method for manufacturing a semiconductor device in accordance with the embodiment of the present invention.

FIG. 16 schematically shows a cross-sectional view illustrating a step in the method for manufacturing a semiconductor device in accordance with the embodiment of the present invention.

FIG. 17 schematically shows a cross-sectional view illustrating a step in the method for manufacturing a semiconductor device in accordance with the embodiment of the present invention.

FIG. 18 schematically shows a cross-sectional view illustrating a step in the method for manufacturing a semiconductor device in accordance with the embodiment of the present invention.

### DETAILED DESCRIPTION

Next, an example of an embodiment of the present invention will be described.

1. Semiconductor Device

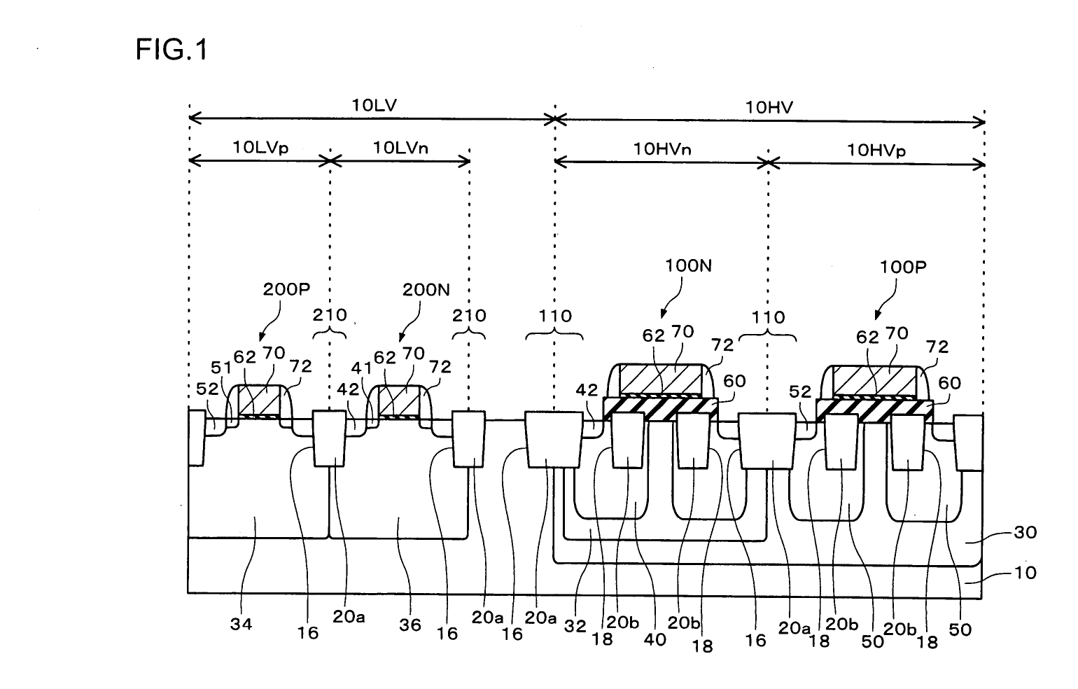

FIG. 1 shows a cross-sectional view schematically indicating a semiconductor device in accordance with an embodiment of the present invention.

The semiconductor device in accordance with the present embodiment is provided with high breakdown voltage transistors 100P and 100N and low voltage driving transistors 200P and 200N mix-mounted on a semiconductor substrate 10 that is a semiconductor layer. A high breakdown voltage transistor region 10HV and a low voltage driving transistor region 10LV are provided in the semiconductor substrate 10. The high breakdown voltage transistor region 10HV includes a P-channel high breakdown voltage transistor region 10HVp and an N-channel high breakdown voltage transistor region 10HVn. The low voltage driving transistor region 10LV includes a P-channel low voltage driving transistor region 10LVp and an N-channel low voltage driving transistor region 10LVn. A P-channel high breakdown voltage transistor 100P is formed in the P-channel high breakdown voltage transistor region 10HVp, and an N-channel high breakdown voltage transistor 100N is formed in the N-channel high breakdown voltage transistor region 10HVn. Similarly, a P-channel low voltage driving transistor 200P is formed in the P-channel low voltage driving transistor region 10LVp, and an N-channel low voltage driving transistor 200N is formed in the N-channel low voltage driving transistor region 10LVn.

In other words, on the same substrate (on the same chip), the P-channel high breakdown voltage transistor 100P, the N-channel high breakdown voltage transistor 100N, the P-channel low voltage driving transistor 200P and the N-channel low voltage driving transistor 200N are mix-mounted. It is noted that FIG. 1 shows only four transistors for the sake of convenience, but it goes without saying that a plurality of various kinds of transistors may be formed on the same substrate.

1.1 High Breakdown Voltage Transistor Region

First, the high breakdown voltage transistor region 10HV will be described. In the high breakdown voltage transistor region 10HV, the P-channel high breakdown voltage transistor region 10HVp and the N-channel high breakdown voltage transistor region 10HVn are provided. A first element isolation region 110 is provided between the adjacent high breakdown voltage transistor regions. More specifically, the first element isolation region 110 is provided between the adjacent P-channel high breakdown voltage transistor 100P and N-channel high breakdown voltage transistor 100N. The first element isolation region 110 is formed from a trench dielectric layer 20a.

Next, the structure of the P-channel high breakdown voltage transistor 100P and the N-channel high breakdown voltage transistor 100N will be described.

The P-channel high breakdown voltage transistor 100P includes a gate dielectric layer 60, offset dielectric layers 20b that are composed of trench dielectric layers, a gate electrode 70, P-type low concentration impurity layers 50, sidewall dielectric layers 72, and P-type high impurity concentration layers 52.

The gate dielectric layer 60 is a film formed by a CVD method, and is formed in a manner to cover areas above an N-type well 30 that forms a channel region, and above the offset dielectric layers 20b. The gate electrode 70 is formed on the gate dielectric layer 60. The P-type low concentration impurity layers 50 define offset regions. The sidewall dielectric layers 72 are formed on the side surfaces of the gate electrode 70. The P-type high concentration impurity layers 52 are provided outside the sidewall dielectric layers 72. The P-type high concentration impurity layer 52 serves as a source region or a drain region (hereafter referred to as a “source/drain region”).

The N-channel high breakdown voltage transistor 100N includes a gate dielectric layer 60, offset dielectric layers 20b that are composed of trench dielectric layers, a gate electrode 70, N-type low concentration impurity layers 40, sidewall dielectric layers 72, and N-type high concentration impurity layers 42.

The gate dielectric layer 60 is a film formed by a CVD method, and is provided in a manner to cover areas above a P-type well 32 that forms a channel region, and above the offset dielectric layers 20b. The gate electrode 70 is formed on the gate dielectric layer 60. The N-type low concentration impurity layers 40 define offset regions. The sidewall dielectric layers 72 are formed on the side surfaces of the gate electrode 70. The N-type high concentration impurity layers 42 are provided outside the side wall dielectric layers 72. The N-type high concentration impurity layer 42 defines a source/drain region.

1.2 Low Voltage Driving Transistor Region

Next, the low voltage driving transistor region 10LV will be described. The low voltage driving transistor region 10LV is provided with a P-channel low voltage driving transistor region 10LVp and an N-channel low voltage driving transistor region 10LVn. A second element isolation region 210 is provided between the adjacent low voltage driving transistor regions. In other words, the second element isolation region 210 is provided between adjacent P-channel low voltage driving transistor 200P and N-channel low voltage driving transistor 200N. The second element isolation region 210 is formed from a trench dielectric layer 20a like the first element isolation region 110.

Next, the structure of each of the transistors will be described.

The N-channel low voltage driving transistor 200N includes a gate dielectric layer 62, a gate electrode 70, sidewall dielectric layers 72, N-type low concentration impurity layers 41, and N-type high concentration impurity layers 42.

The gate dielectric layer 62 is provided on a P-type well 36 that forms a channel region. The gate electrode 70 is formed on the gate dielectric layer 62. The sidewall dielectric layers 72 are formed on the side surfaces of the gate electrode 70. The N-type low concentration impurity layers 41 and N-type high concentration impurity layers 42 form source/drain regions with an LDD structure.

The P-channel low voltage driving transistor 200P includes a gate dielectric layer 62, a gate electrode 70, sidewall dielectric layers 72, P-type low concentration impurity layers 51, and P-type high concentration impurity layers 52.

The gate dielectric layer 62 is provided on an N-type well 34 that forms a channel region. The gate electrode 70 is formed on the gate dielectric layer 62. The sidewall dielectric layers 72 are formed on the side surfaces of the gate electrode 70. The P-type low concentration impurity layers 51 and P-type high concentration impurity layers 52 form source/drain regions with an LDD structure.

The semiconductor device in accordance with the present embodiment provides the following advantages.

In the semiconductor device in accordance with the present embodiment, the gate dielectric layers 60 of the high breakdown voltage transistors 100P and 100N are films that are formed by a CVD method, such that the semiconductor device with the gate dielectric layers 60 having a uniform film thickness can be provided. Ordinarily, gate dielectric layers 60 are formed by a thermal oxidation method. For example, when a gate dielectric layer is formed by a thermal oxidation method over an offset dielectric layer composed of a trench dielectric layer, thinning occurs at the upper end sections of the trench dielectric layer, and the gate dielectric layer may not be formed with a uniform film thickness. However, due to the fact that the semiconductor device in accordance with the present embodiment has the gate dielectric layers 60 formed by a CVD method, such problems can be avoided, and a semiconductor device with an improved reliability can be provided.

2. Method For Manufacturing A Semiconductor Device

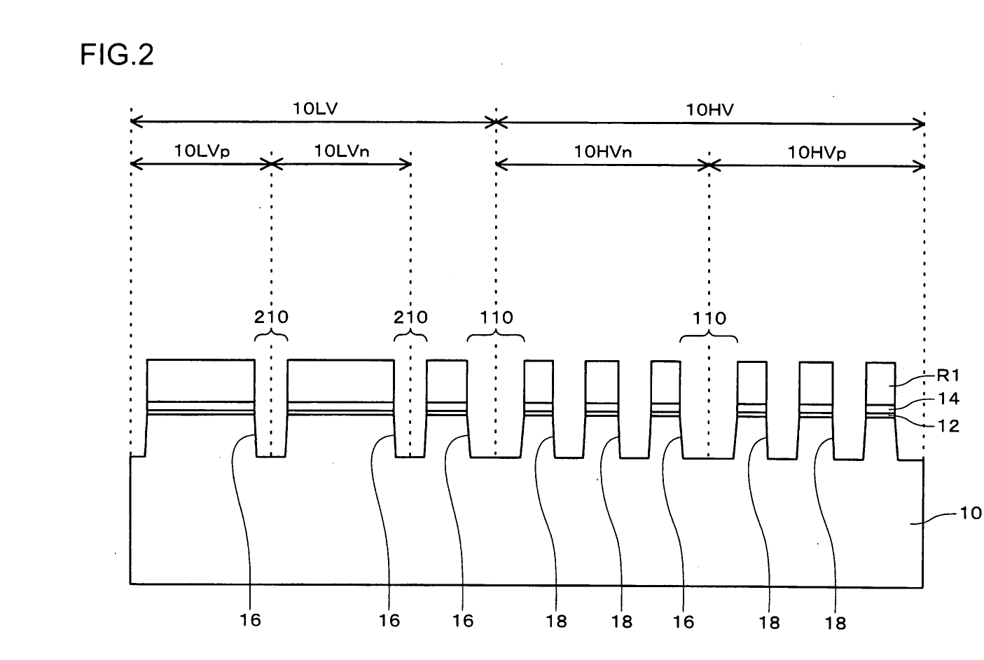

Next, a method for manufacturing a semiconductor device will be described with reference to FIGS. 2-19. FIGS. 2-19 show cross-sectional views schematically indicating steps in the method for manufacturing a semiconductor device in accordance with an embodiment of the present invention.

(1) Initially, first element isolation regions 110 for defining a high breakdown voltage transistor forming region 10HV, second element isolation regions 210 for defining a low voltage driving transistor forming region 10LV, and offset dielectric layers for high breakdown voltage transistors are formed.

As shown in FIG. 2, a pad oxide film 12, a stopper layer 14 and a resist layer R1 having a predetermined pattern are formed on the semiconductor substrate 10 by using known lithography and etching techniques. A silicon nitride film can be used as the stopper layer 14. The resist layer R1 defines openings above regions where the first element isolation regions 110, the second element isolation regions 210 and offset dielectric layers for alleviating the electric fields of high breakdown voltage transistors are formed.

Then, the semiconductor substrate 10 is etched by using the resist layer R1, the stopper layer and the pad oxide film 12 as a mask. In this way, trenches 16 and 18 are formed.

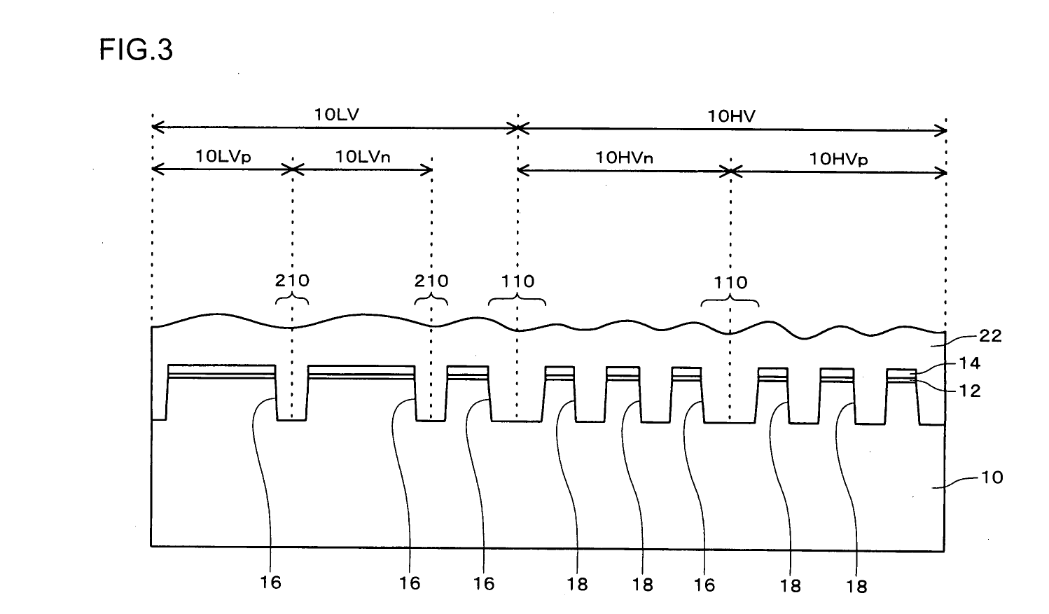

(2) Next, trench oxide films (not shown) are formed on surfaces of the trenches 16 and 18. The trench oxide films may be formed by, for example, a thermal oxidation method. The film thickness of the trench oxide films may be, for example, 30-50 nm. Then, as shown in FIG. 3, a dielectric layer 22a is deposited over the entire surface to thereby embed the trenches 16 and 18. The dielectric layer 22a can be deposited by a generally known method for forming dielectric layers.

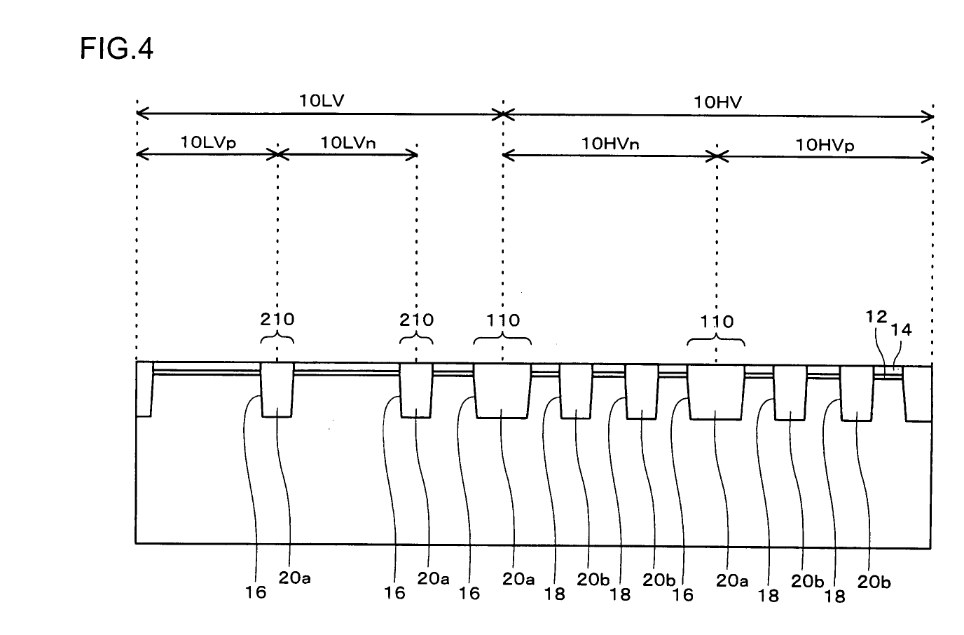

(3) Next, as shown in FIG. 4, the dielectric layer 22a is removed until the stopper layers 14 are exposed. The dielectric layer 22a can be removed by, for example, a CMP method. In this way, trench dielectric layers 20a are embedded in the trenches 16. Similarly, the dielectric layers are also embedded in the trenches 18, thereby forming offset dielectric layers 20b. Then, the stopper layers 14 are removed by heated phosphoric acid, and the pad oxide films 12 are removed by hydrofluoric acid. By steps (1)-(3) above, the first element isolation regions 110, the second element isolation regions 210 and the offset dielectric layers 20b are formed.

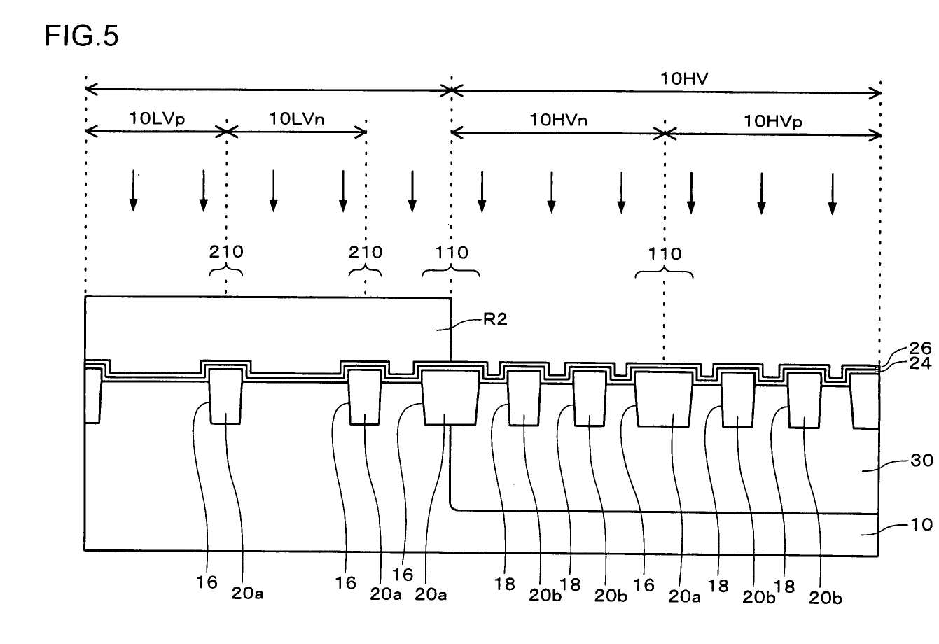

(4) Next, as shown in FIG. 5, an N-type well 30 is formed in the high breakdown voltage transistor region 10HV. First, a sacrificial oxide film 24 is formed over the entire surface of the semiconductor substrate 10.

As the sacrificial oxide film 24, for example, a silicon oxide film may be formed. Then, on the entire surface in the high breakdown voltage transistor region 10HV and the low voltage driving transistor region 10LV, a silicon nitride film 26 is formed. Then, a resist layer R2 having a specified pattern is formed, and an N-type impurity such as phosphorous or arsenic is injected at least one time in the semiconductor substrate 10 by using the resist layer R2 as a mask, thereby forming the N-type well 30 in the semiconductor substrate 10. Then, the resist layer R2 is removed by, for example, ashing, and the semiconductor substrate 10 is thermally treated, thereby diffusing the impurity.

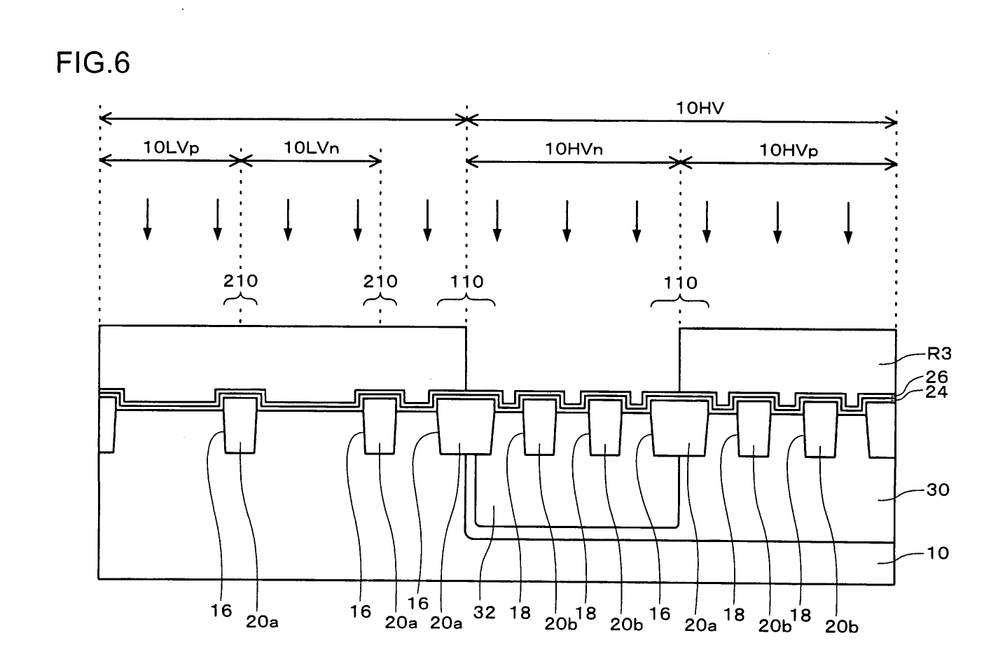

(5) Next, as shown in FIG. 6, a P-type well 32 is formed in the high breakdown voltage transistor region 10HV. First, a resist layer R3 having a specified pattern is formed. P-type impurity ions are injected at least one time in the semiconductor substrate 10 by using the resist layer R3 as a mask, thereby forming the P-type well 32. Then, the resist layer R3 is removed by ashing, and the semiconductor substrate 10 is thermally treated, thereby diffusing the impurity.

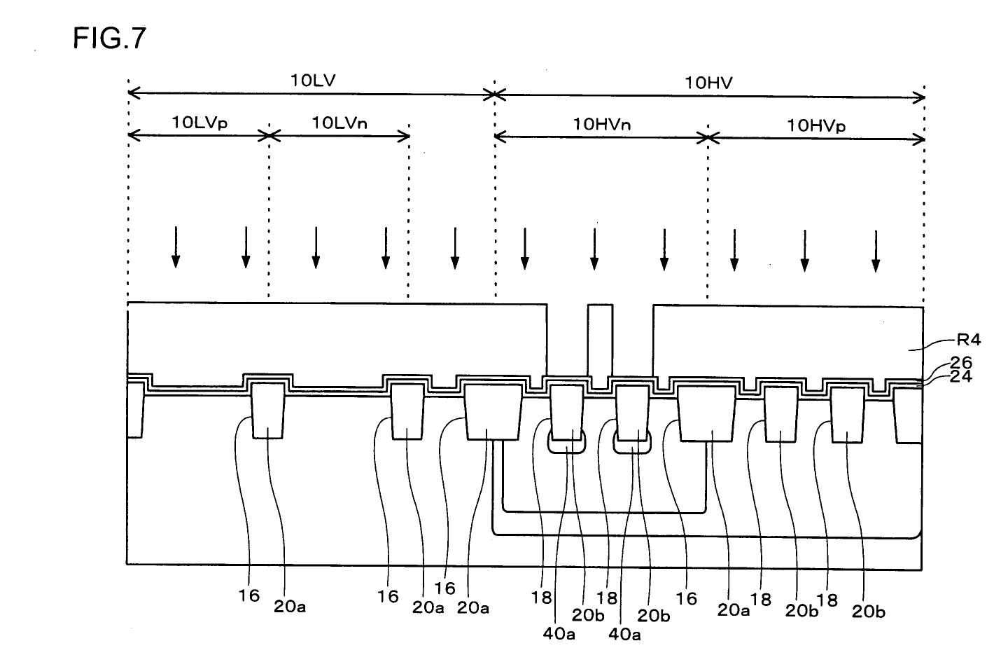

(6) Next, as shown in FIG. 7, impurity layers for offset regions of source/drain regions are formed in the high breakdown voltage transistor region 10HV.

First, a resist layer R4 that covers specified regions is formed. A P-type impurity is introduced in the semiconductor substrate 10 by using the resist layer R4 as a mask, thereby forming impurity layers 40a. Then, the resist layer R4 is removed.

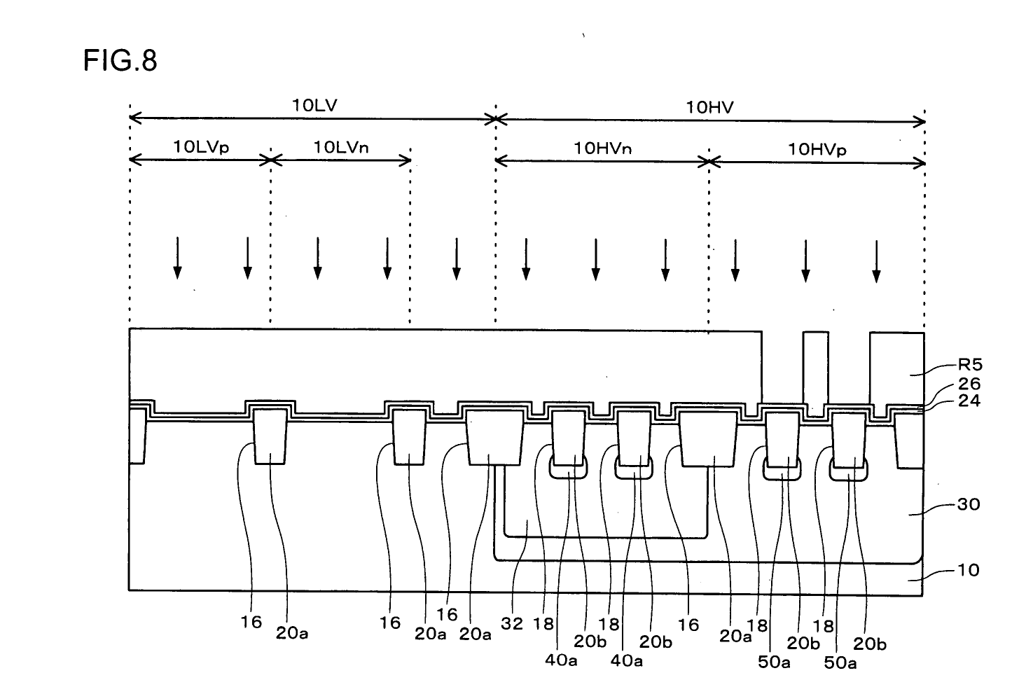

(7) Next, as shown in FIG. 8, a resist layer R5 that covers specified regions is formed. A P-type impurity is introduced in the semiconductor substrate 10 by using the resist layer R5 as a mask. In this way, impurity layers 50a for offset regions of source/drain regions are formed in the P-channel high breakdown voltage transistor region 10Hvp.

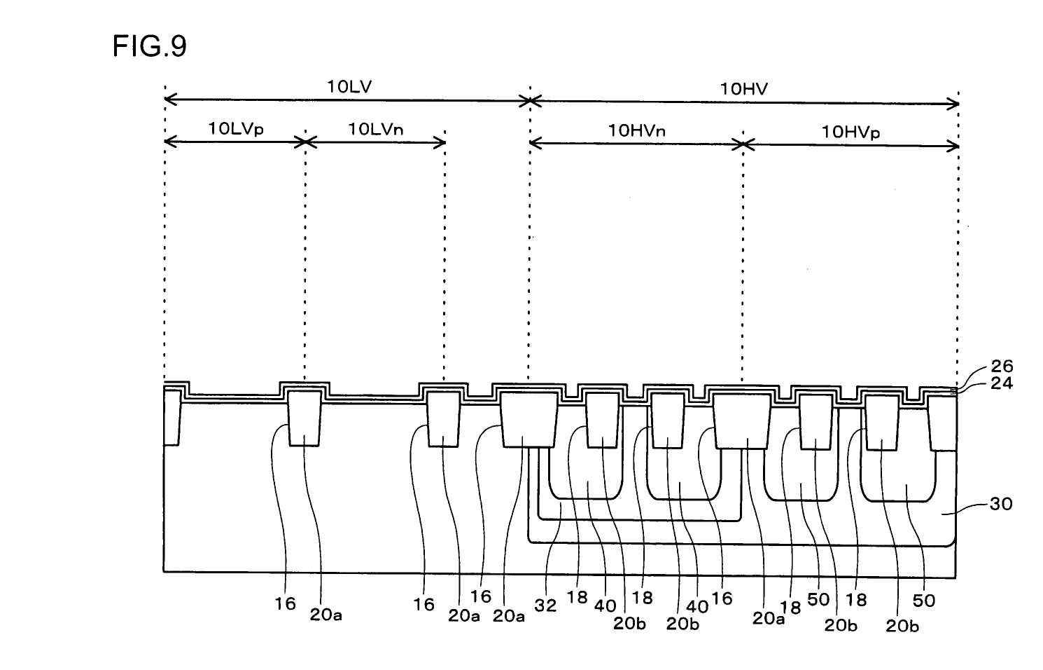

(8) Next, as shown in FIG. 9, by conducting a heat treatment by a known technique, the impurity layers are diffused. By steps (6)-(8) above, low concentration impurity layers 40 and 50 that become offset regions of the high breakdown voltage transistors 100P and 100N are formed.

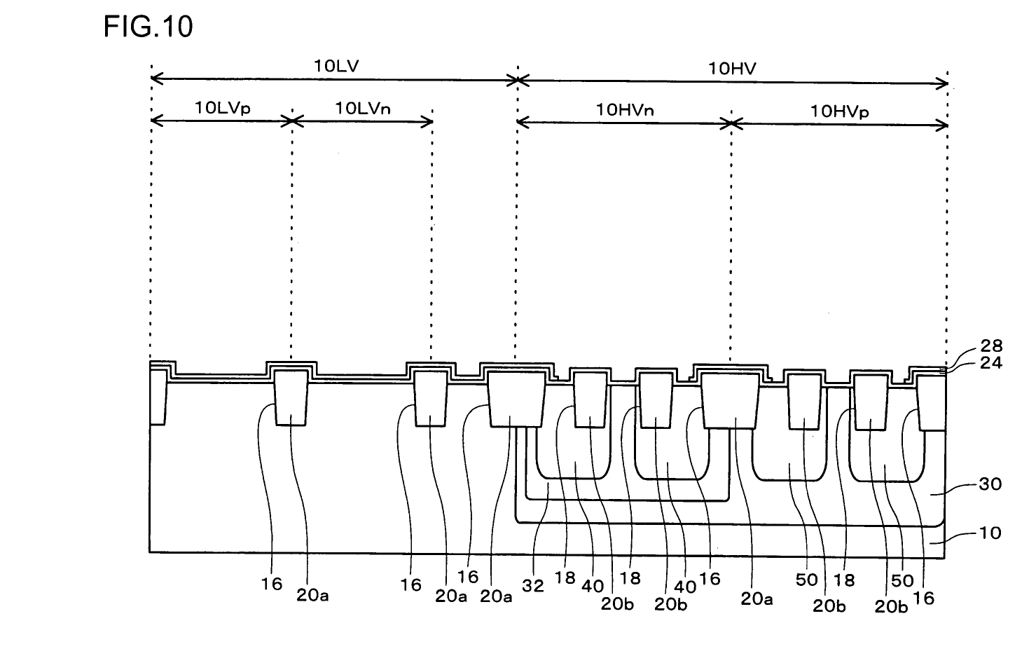

(9) Then, as shown in FIG. 10, a protection film 28 is formed with a pattern that covers areas other than the regions where gate dielectric layers 60 of the high breakdown voltage transistors 100P and 100N are to be formed. The protection film 28 may be formed by forming on the silicon nitride film 26 a resist layer (not shown) having openings at regions where the gate dielectric layers 60 are to be formed in a later step, and patterning the silicon nitride film 26 using the resist layer as a mask.

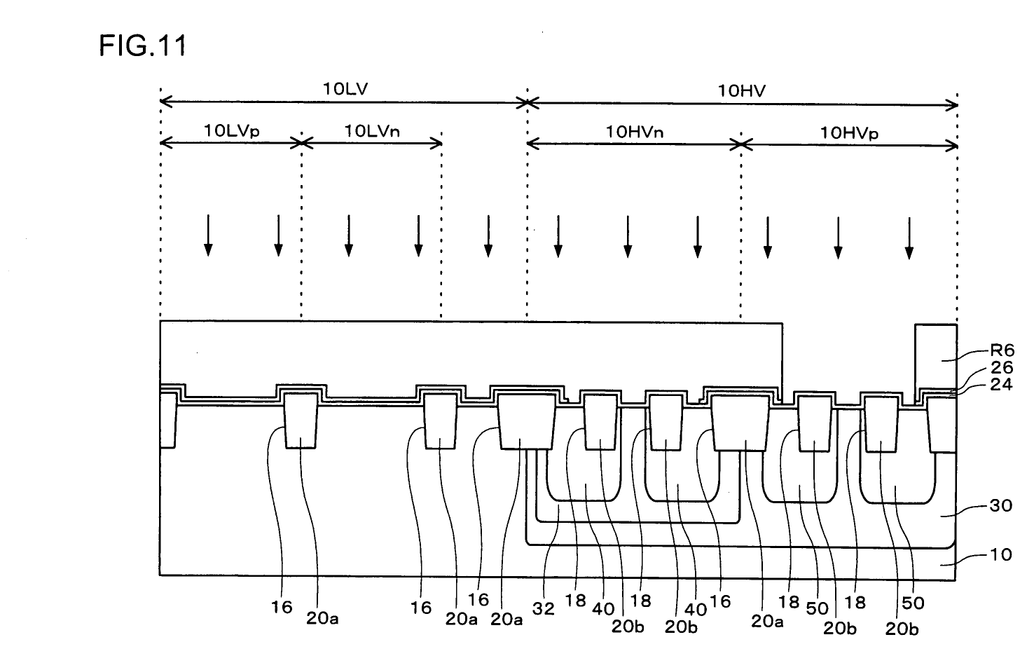

(10) Next, channel doping is conducted in the high breakdown voltage transistor forming region 10HV if necessary. As shown in FIG. 11, a resist layer R6 is formed in a manner to cover regions other than the P-channel high breakdown voltage transistor region 10HVp. By using the resist layer R6 as a mask, a P-type impurity, such as, for example, boron is injected, to thereby conduct channel doping for the high breakdown voltage transistor 100P. Then, the resist layer R6 is removed by ashing.

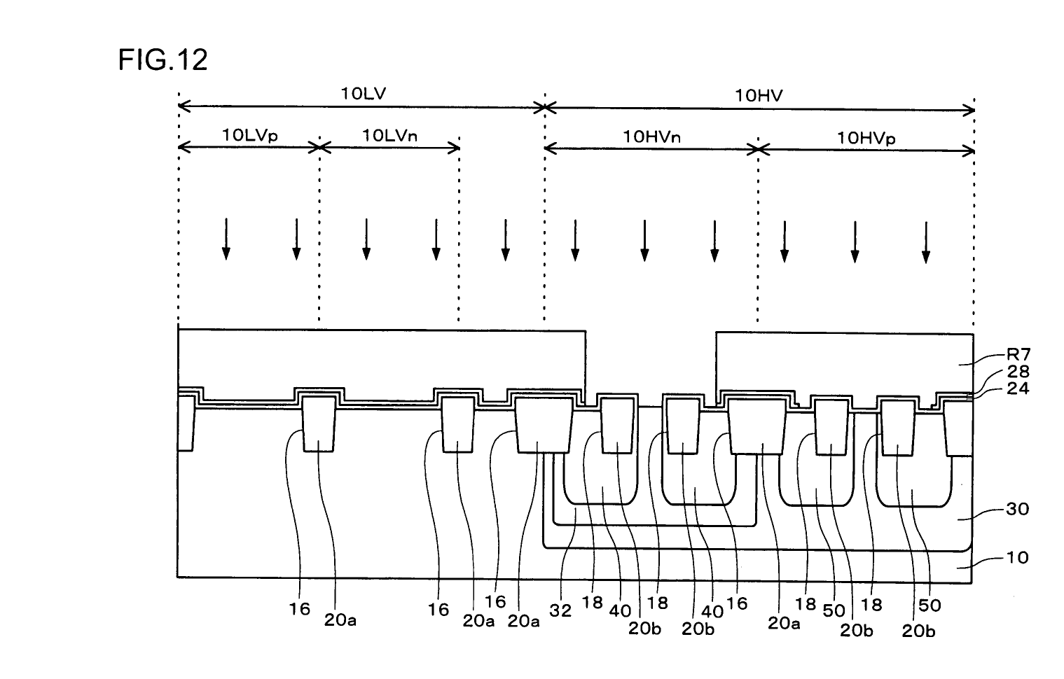

(11) Next, channel doping is conducted for the N-channel high breakdown voltage transistor 100N. As shown in FIG. 12, a resist layer R7 is formed in a manner to cover regions other than the N-channel high breakdown voltage transistor region 10HVn. By using the resist layer R7 as a mask, an N-type impurity, such as, for example, phosphorus is injected, to thereby conduct channel doping for the high breakdown voltage transistor 100N. Then, the resist layer R7 is removed by ashing.

(12) Next, portions that are not covered by the protection film 28 that is formed in step (9) described above, in other words, exposed portions of the sacrificial oxide film 24, are removed by hydrofluoric acid.

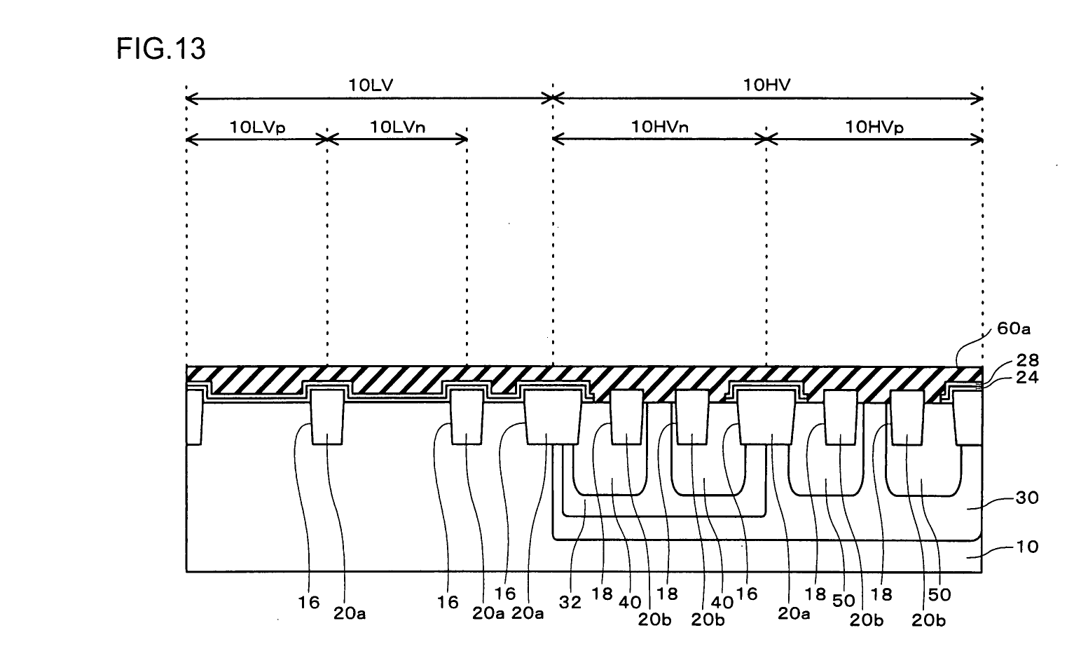

Next, as shown in FIG. 13, a dielectric layer 60a that becomes the gate dielectric layers 60 of the high breakdown voltage transistors is formed over the entire surface of the semiconductor substrate 10. The dielectric layer 60 may be formed by, for example, a CVD method. In particular, the dielectric layer 60a may preferably be formed by a high temperature CVD method. With the high temperature CVD method, the film forming rate is 0.1-4 nm/min, and a film having a higher density and better characteristics can be formed, compared to those formed by a normal CVD method. The film thickness of the dielectric layer 60a may be, for example, about 100-160 nm. Also, before the dielectric layer 60a is formed, an oxide film (not shown) can be formed on the semiconductor substrate 10. This oxide film can be formed by, for example, a thermal oxidation method, and its film thickness is about 10-30 nm. Advantages in forming the oxide film before forming the dielectric layer 60a include the following. (a) By forming the oxide film, the surface of the semiconductor substrate 10 that is roughened by injections of various impurities and heat treatments can be made better. By forming the dielectric layer 60a on the oxide film having a good surface condition, the gate dielectric layers 60 can be formed with a higher density and a better film quality. (b) By forming the dielectric layer by a CVD method directly on the semiconductor substrate 10, damages may be inflicted on the semiconductor substrate 10. However, by forming the oxide film in advance, the semiconductor substrate 10 can be prevented from damage. (c) A single oxide film formed by a CVD method is difficult to provide a breakdown voltage and a leak current characteristic that are comparable to a thermal oxidation film, but they can be supplemented and good characteristics can be obtained through forming a thermal oxidation film in advance to thereby form a stacked layered structure with a CVD film.

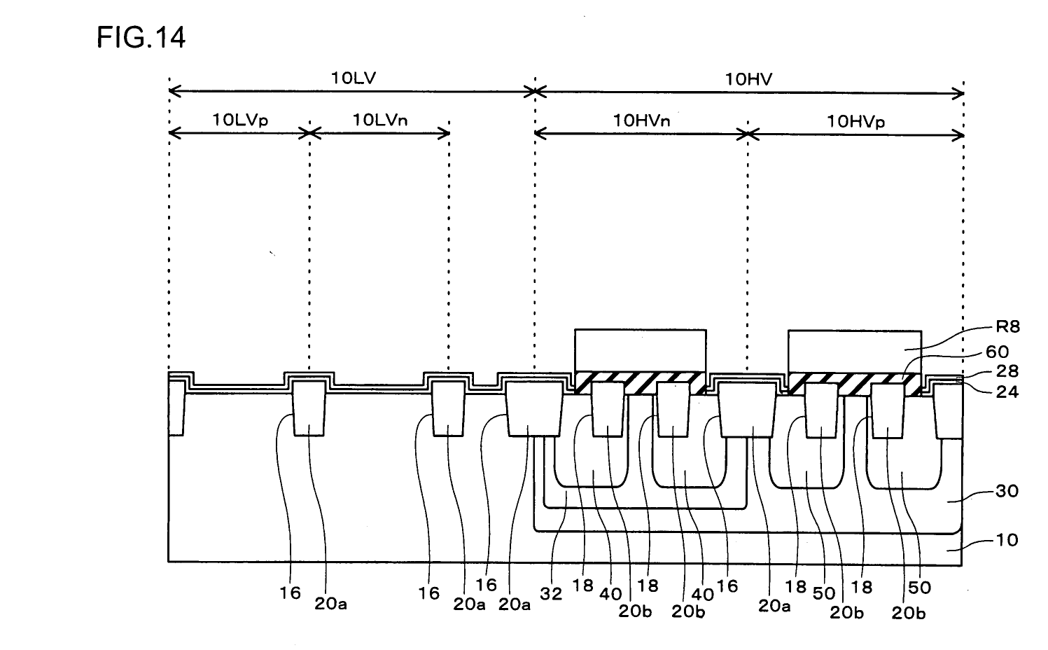

(13) Next, as shown in FIG. 14, the dielectric layer 60a is patterned to thereby form the gate dielectric layers 60. In patterning the dielectric layer 60a, a resist layer R8 having a pattern for the gate dielectric layers 60 is formed first. By using the resist layer R8 as a mask, portions of the dielectric layer 60a are removed, thereby forming the gate dielectric layers 60. When removing the dielectric layer 60a, the resist layer R8 is to have a pattern that covers the offset dielectric layers 20b. This is to prevent the offset dielectric layers 20b from partially being etched together with the dielectric layer 60a, which would happen if the dielectric layer 60a is removed in a state in which portions of the offset dielectric layers 20b are exposed.

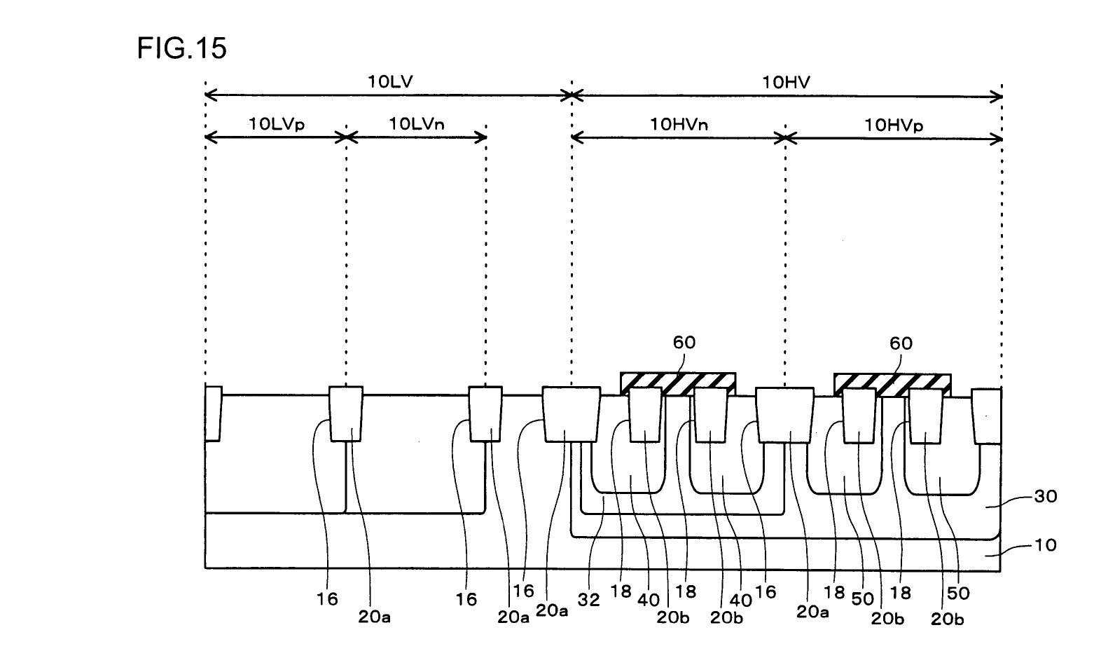

(14) Next, as shown in FIG. 15, the protection film 28 is removed. Then, the resist layer R8 is removed by ashing, for example.

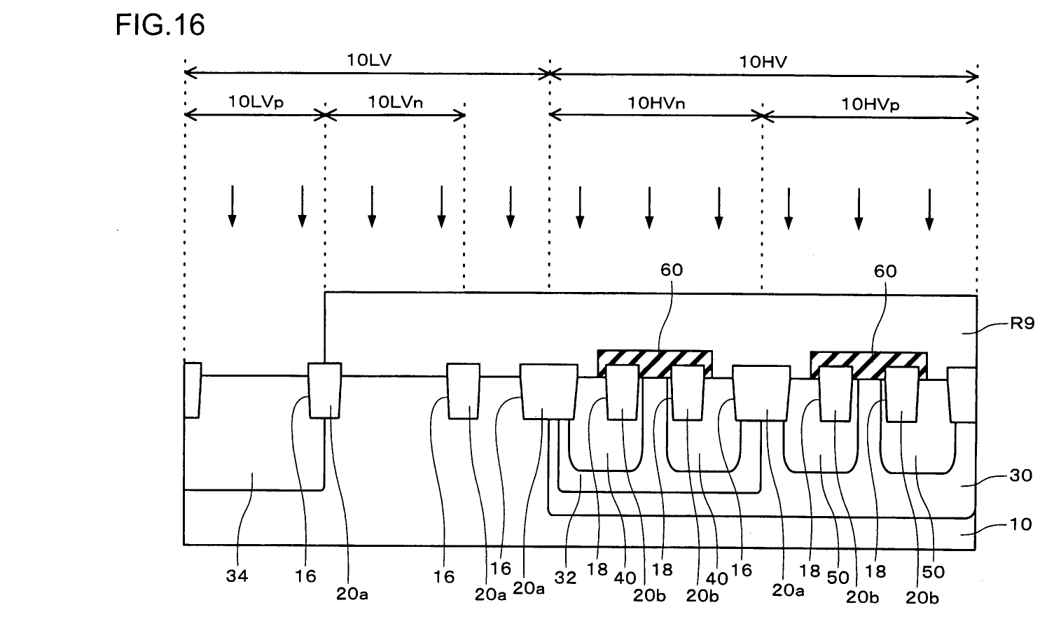

(15) Next, as shown in FIG. 16, a well is formed in the low voltage driving transistor region 10LV. First, a resist layer R9 is formed in a manner to cover regions other than the P-channel low voltage driving transistor forming region 10LVp. Then, by using the resist layer R9 as a mask, an N-type impurity such as phosphorous, arsenic or the like is injected at least one time, thereby forming an N-type well 34. Then, the resist layer R9 is removed.

(16) Next, a resist layer is formed in a manner to cover regions other than the N-channel low voltage driving transistor forming region 10LVn. Then, by using the resist layer as a mask, a P-type impurity such as boron or the like is injected at least one time, thereby forming a P-type well 36. Then, the resist layer is removed. Then, channel doping may be conducted depending on the design requirements.

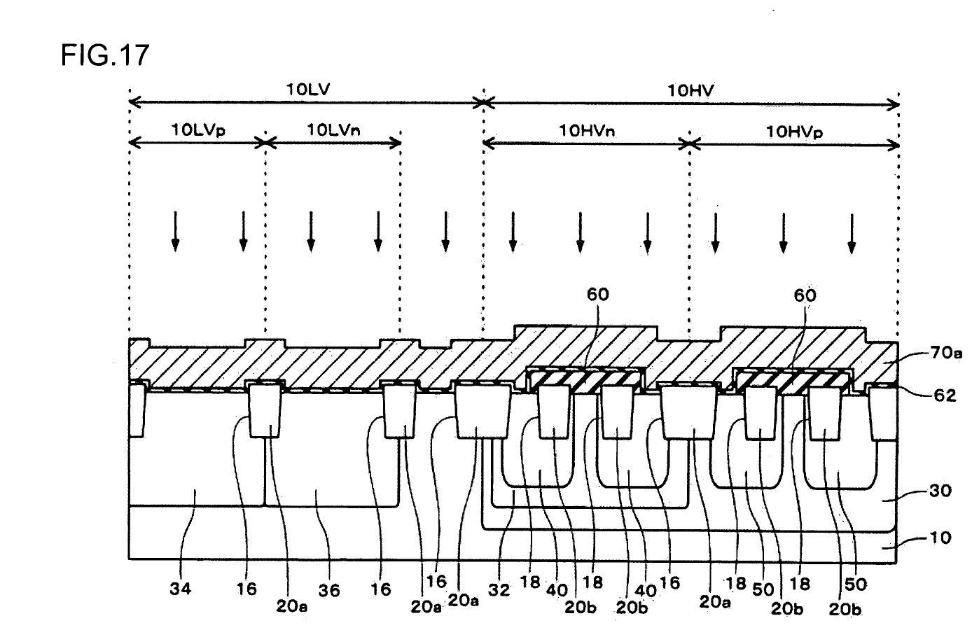

(17) Next, as shown in FIG. 17, gate dielectric layers 62 for the low voltage driving transistors 200P and 200N are formed. The gate dielectric layers 62 may be formed by, for example, a thermal oxidation method. The film thickness of the gate dielectric layers 62 can be 35 Å, for example. The gate dielectric layers 62 are also formed in the high breakdown voltage transistor region 10HV.

Then, as shown in FIG. 17, a conductive layer 70a is formed on the entire surface in the high breakdown voltage transistor region 10HV and the low voltage driving transistor region 10LV. As the conductive layer 70a, for example, a polysilicon layer is formed. When a polysilicon layer is used as the material of the conductive layer 70a, an N-type impurity may be injected in regions in the conductive layers 70a which are to become gate electrodes of the N-channel high breakdown voltage transistor 100N and the N-channel low voltage driving transistor 200N, to thereby lower the resistance of the gate electrodes.

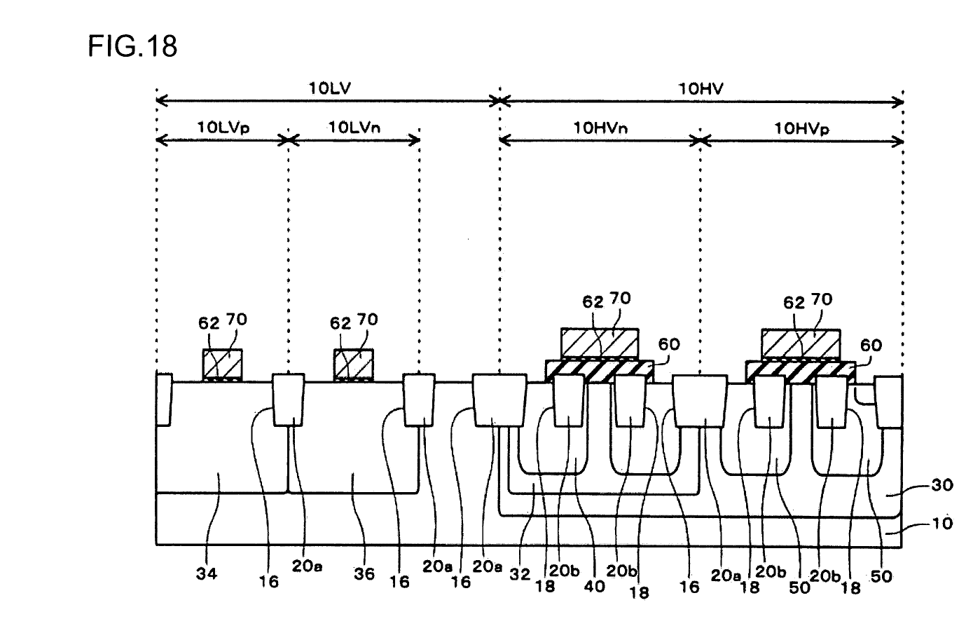

Next, a resist layer (not shown) having a specified pattern is formed. By using the resist layer as a mask, the polysilicon layer is patterned, thereby forming gate electrodes 70, as shown in FIG. 18.

(18) Next, low concentration impurity layers 41 and 51 (see FIG. 1) for the respective transistors 200P and 200N are formed in the low voltage driving transistor region 10LV. The low concentration impurity layers 41 and 51 can be formed by forming a mask layer using known lithography and etching techniques, and injecting a specified impurity.

Then, by forming a dielectric layer (not shown) over the entire surface, and anisotropically etching the dielectric layer, sidewall dielectric layers 72 (see FIG. 1) are formed on the side surfaces of the gate electrodes 70.

Then, by introducing a P-type impurity in specified regions of the P-channel high breakdown voltage transistor region 10HVp and the P-channel low voltage driving transistor region 10LVp, as shown in FIG. 1, P-type high concentration impurity layers 52 that become source/drain regions can be formed outside the sidewall dielectric layers 72.

Then, by introducing an N-type impurity in specified regions of the N-channel high breakdown voltage transistor region 10HVn and the N-channel low voltage driving transistor region 10LVn, N-type high concentration impurity layers 42 that become source/drain regions can be formed.

Advantages of the semiconductor device in accordance with the present embodiment include the following.

In the method for manufacturing a semiconductor device in accordance with the present embodiment, the gate dielectric layers 60 of the high breakdown voltage transistors 100P and 100N are formed by a CVD method. For this reason, the gate dielectric layers 60 can be formed with a uniform film thickness. The film thickness of the gate dielectric layers 60 of the high breakdown voltage transistors 100P and 100N may exceed 100 nm, and the following problems may occur if the gate dielectric layers 60 having such a great film thickness are formed by a thermal oxidation method. When offset dielectric layers of high breakdown voltage transistors are formed with trench dielectric layers, and gate dielectric layers having a great film thickness are formed over the trench dielectric layers by a thermal oxidation method, thinning occurs at the upper end sections of the trench dielectric layers, and the gate dielectric layers cannot be formed with a uniform film thickness. However, by the method for manufacturing a semiconductor device in accordance with the present invention, because the gate dielectric layers are formed by a CVD method, such problems are avoided, and semiconductor devices having an improved reliability can be manufactured.

With the semiconductor device in accordance with the present embodiment, the first element isolation regions 110, the second element isolation regions 210 and the offset dielectric layers 20b of the high breakdown voltage transistors 100P and 100N can be formed by the same process. For this reason, the number of steps can be reduced. As a result, there can be provided a method for manufacturing semiconductor devices in which the cost and time for manufacturing are reduced.

It is noted that the present invention is not limited to the embodiment described above, and many modifications can be made within the scope of the present invention. In the present embodiment, an example that uses a semiconductor substrate in a bulk form is described, but a SOI substrate may be used.

1. A semiconductor device comprising:
a semiconductor layer;
a first element isolation region defining a high breakdown voltage transistor forming region in the semiconductor layer;
a second element isolation region defining a low voltage driving transistor forming region in the semiconductor layer;
a high breakdown voltage transistor formed in the high breakdown voltage transistor forming region;
a low voltage driving transistor formed in the low voltage driving transistor forming region; and
an offset dielectric layer for alleviating an electric field of the high breakdown voltage transistor,
wherein the high breakdown voltage transistor includes a chemical vapor deposited gate dielectric layer.

2. A semiconductor device according to claim 1, wherein the gate dielectric layer of the high breakdown voltage transistor has a film thickness of about 100-160 nm.

3. A semiconductor device according to claim 1, wherein the offset dielectric layer comprises a trench dielectric layer.

4. A method for manufacturing a semiconductor device, comprising:
a step of forming a first element isolation region defining a high breakdown voltage transistor forming region in a semiconductor layer;
a step of forming a second element isolation region defining a low voltage driving transistor forming region in the semiconductor layer;
a step of forming an offset dielectric layer for alleviating an electric field of the high breakdown voltage transistor;
a step of forming a high breakdown voltage transistor in the high breakdown voltage transistor forming region; and
a step of forming a low voltage driving transistor in the low voltage driving transistor forming region,
wherein a gate dielectric layer of the high breakdown voltage transistor is formed by a CVD method.

5. A method for manufacturing a semiconductor device according to claim 4, wherein the offset dielectric layer is formed by a trench element isolation method.

6. A method for manufacturing a semiconductor device according to claim 4, wherein the first and second element isolation regions and the offset dielectric layer are formed by a common process.
